(19) United States
(12) Patent Application Publication
(10) Pub. No.: US 2024/0319248 A1
(43) Pub. Date: Sep. 26, 2024

(54) SIGNAL PROCESSING METHOD, MEASUREMENT INSTRUMENT AND MEASUREMENT SYSTEM

(71) Applicant: Rohde & Schwarz GmbH & Co. KG, Muenchen (DE)

(72) Inventors: Florian Ramian, Muenchen (DE); Andreas Lagler, Muenchen (DE); Karolin Werthmueller, Muenchen (DE)

(73) Assignee: Rohde & Schwarz GmbH & Co. KG, Muenchen (DE)

(21) Appl. No.: 18/187,209

(22) Filed: Mar. 21, 2023

(51) Int. Cl. G01R 29/26

(52) U.S. Cl. CPC G01R 29/26

(57) ABSTRACT

A signal processing method is provided for processing a digital input signal. The method may be carried out by a measurement instrument. The measurement instrument includes a signal input, a measurement circuit, and an analysis circuit. The signal processing method includes the steps of: receiving a digital input signal from a device under test; capturing a first number N₁ of IQ measurement sets based on the received digital input signal, wherein each IQ measurement set comprises a plurality of IQ measurement points; determining an IQ average based on the captured IQ measurement sets, thereby obtaining an averaged signal; determining a second number N₂ of noise vectors based on the averaged signal and based on the captured IQ measurement sets; and averaging over the determined noise vectors, thereby obtaining an averaged noise vector.

### FIELD OF THE DISCLOSURE

Embodiments of the present disclosure generally relate to a signal processing method of processing a digital input signal by a measurement instrument. Embodiments of the present disclosure further relate to a measurement instrument and to a measurement system.

### BACKGROUND

The noise figure is a measure that is of interest for characterizing the behavior of a device under test under operation, for instance a communication device such as a user end device or any other signal processing device.

If noise requirements on a particular device under test are strict, i.e. the device under test may only generate small amounts of noise in order to pass a certain test, additional noise generated by the measurement equipment itself may become highly relevant.

Noise-reduction techniques are known that reduce the overall noise level of a signal chain. However, these techniques do not distinguish between different sources of the noise such that the noise generated by the device under test may inadvertently be reduced as well. Thus, the noise figure of the device under test cannot be measured precisely with these techniques.

A way to circumvent this problem is using high-quality measurement instruments having a particularly low inherent noise level. However, such measurement instruments are rather expensive.

Thus, there is a need for a signal processing method, for a measurement instrument, as well as for a measurement instrument that allow for a cost-efficient assessment of a noise contribution of a device under test.

### SUMMARY

Embodiments of the present disclosure provide a signal processing method of processing a digital input signal by a measurement instrument. The measurement instrument comprises, for example, a signal input, a measurement circuit, and an analysis circuit. In an embodiment, the signal processing method comprises the steps of: receiving, by the signal input, a digital input signal from a device under test, capturing, by the measurement circuit, a first number N₁ of IQ measurement sets based on the received digital input signal, wherein each IQ measurement set comprises a plurality of IQ measurement points, determining, by the analysis circuit, an IQ average based on the captured IQ measurement sets, thereby obtaining an averaged signal, determining, by the analysis circuit, a second number N₂ of noise vectors based on the averaged signal and based on the captured IQ measurement sets, and averaging, by the analysis circuit, over the determined noise vectors, thereby obtaining an averaged noise vector.

Therein, the N₁ IQ measurement sets may correspond to N₁ iterations of the same measurement conducted on the same digital input signal or on the same portion of the digital input signal.

In some embodiments, the IQ average is determined by averaging over corresponding IQ measurement points of at least two of the IQ measurement sets.

In some embodiments, the IQ measurement points may also be called “IQ measurement samples”.

In general, when performing the IQ average, noise comprised in the captured IQ measurement sets cancels at least partially, for example completely. Therein, the noise cancels regardless of its origin, i.e. regardless of whether the noise originates in the device under test or in the measurement instrument.

Accordingly, in the averaged signal, noise contributions from all sources are suppressed.

The signal processing method according to the present disclosure is based on the idea to determine the noise generated by the device under test by determining the second number N₂ of noise vectors based on the averaged signal and based on the captured IQ measurement sets. The determined noise vectors are averaged, such that the averaged noise vector corresponds to an averaged error vector magnitude (EVM) associated with the device under test. Thus, the signal processing method according to the present disclosure allows to perform both IQ averaging and EVM averaging on the set of N₁ IQ measurement sets, such that the noise contribution of the device under test can be determined with high precision and with reduced measurement uncertainty, respectively.

Further, the necessary measurement time is reduced, as the set of N₁ IQ measurement sets can be used for both the IQ averaging and the EVM averaging. In other words, no separate measurements are required for performing the IQ averaging and the EVM averaging.

In some embodiments, the signal processing method according to the present disclosure allows for reusing measurement results that have been obtained in previous measurements, such that the overall measurement time is reduced.

For example, if an averaged IQ signal has been determined in a previous measurement, the measurement results can be reused for the signal processing method according to the present disclosure, namely for determining the averaged noise vector.

As another example, if an averaged EVM has been determined in a previous measurement, the measurement results can be reused for the signal processing method according to the present disclosure, namely for determining the IQ average.

In some embodiments, the digital input signal does not necessarily have to be demodulated for performing the signal processing method according to the present disclosure. Thus, the measurement time necessary to assess the performance of the device under test is further reduced.

According to an aspect of the present disclosure, the determined IQ average corresponds to, for example, an IQ average over (N₁−1) of the captured IQ measurement sets. This way, it is ensured that each of the noise vectors determined is a valid noise vector, as will be described in more detail below.

In some embodiments, the first number N₁ is equal to the second number N₂. Thus, the number of noise vectors determined is equal to the number of IQ measurement sets determined.

In some embodiments, for each IQ measurement set, a corresponding noise vector may be determined.

However, it is also conceivable that N₁ is different from N₂. In some embodiments, N₂ may be smaller than N₁.

In an embodiment of the present disclosure, the noise vectors and/or the averaged noise vector correspond to a noise contribution of the device under test. In other words, the determined noise vectors may comprise only noise contributions from the device under test. Likewise, the averaged noise vector may comprise only noise contributions of the device under test.

In a further embodiment of the present disclosure, the noise vectors are free of noise generated by the measurement instrument at least up to a power-suppressed contribution, and/or wherein the averaged noise vector is free of noise generated by the measurement instrument at least up to a power-suppressed contribution. Thus, the noise vectors essentially comprise only noise originating in the device under test due to the IQ averaging performed. Likewise, the averaged noise vector essentially comprises only noise originating in the device under test due to the IQ averaging performed.

In some embodiments, the contribution of noise originating outside of the device under test is power-suppressed with 1/a, wherein a is the number of IQ measurement sets that are averaged. Accordingly, a may be equal to (N₁−1).

An aspect of the present disclosure provides that each noise vector determined is associated, for example, with one of the captured IQ measurement sets. In other words, a corresponding noise vector may be determined for each of the captured IQ measurement sets.

According to another aspect of the present disclosure, differences between the IQ measurement sets and the averaged signal are determined, for example, in order to determine the noise vectors. In general, the averaged signal is essentially free of noise, i.e. free of noise except for power-suppressed noise contributions. Accordingly, by subtracting the averaged signal from the respective IQ measurement sets, the noise comprised in the individual IQ measurement sets can be extracted.

The differences between the IQ measurement sets and the averaged signal may be multiplied by N₁/(N₁−1) in order to determine the noise vectors. As will be described in more detail below, the factor N₁/(N₁−1) effects that the determined IQ average corresponds to an IQ average over (N₁−1) of the captured IQ measurement sets. Thus, it is ensured that each of the determined noise vectors is a valid noise vector.

In an embodiment of the present disclosure, the differences between the IQ measurement sets and the averaged signal are multiplied by a weighting factor in order to determine the noise vectors. As explained above, the difference between the IQ measurement sets and the averaged signal corresponds to the complete noise comprised in the individual IQ measurement sets. The weighting factor is chosen or rather determined such that the differences between the IQ measurement sets and the averaged signal multiplied by the weighting factor correspond to the noise contribution of the device under test.

In a further embodiment of the present disclosure, the weighting factor depends on at least one of the first number N₁, a root means square (RMS) of a total noise, a RMS noise of an analysis path of the measurement instrument, or a RMS noise of a signal generator path of the measurement instrument.

In some embodiments, the RMS of the total noise, the RMS noise of the analysis path, and/or the RMS noise of the signal generator path can be measured, e.g. by applying a known load to the measurement instrument. For example, the known load may be a standard load that can be used for calibrating the measurement instrument. The first number N₁ is the number of IQ measurements sets taken, and is thus also known. Thus, the weighting factor can be determined based on known and/or measurable quantities.

In some embodiments, amplitudes of the noise vectors are averaged in order to determine the averaged noise vector. The averaged noise vector may have an amplitude being equal to the averaged amplitudes of the noise vectors.

In some embodiments, the phase of the averaged noise vector may be chosen to be equal to a phase of one of the noise vectors. Alternatively, the phase of the averaged noise vector may be equal to an average of the phases of the noise vectors. However, it is to be understood that any other suitable averaging technique may be used.

In some embodiments, a corrected signal may be determined based on the averaged signal and based on the averaged noise vector, wherein the corrected signal comprises noise generated by the device under test. In some embodiments, the corrected signal may be equal to the sum of the averaged signal and the averaged noise vector. Accordingly, the resulting corrected signal may comprise only a useful signal (also called wanted signal) of the device under test and noise contributions of the device under test, at least up to power-suppressed contributions.

Embodiments of the present disclosure further provide a measurement instrument. In an embodiment, the measurement instrument comprises a signal input, a measurement circuit, and an analysis circuit. In some embodiments, the measurement instrument may be configured to perform the signal processing method according to any one of the embodiments described above.

Regarding the further advantages and properties of the measurement instrument, reference is made to the explanations given above with respect to the signal processing method, which also hold for the measurement instrument and vice versa.

For example, the measurement instrument may be established as a vector network analyzer, as a signal analyzer, as a spectrum analyzer, or as an oscilloscope. In some embodiments, the measurement instrument may be established as a digital oscilloscope. However, it is to be understood that the measurement instrument may be established as any other suitable type of measurement instrument being configured to perform measurements on digital signals.

In an embodiment of the present disclosure, the measurement instrument is a calibrated measurement instrument, such that a noise contribution of the measurement instrument is known. In some embodiments, the known noise contribution of the measurement instrument can be used to determine the weighting factor described above.

Embodiments of the present disclosure further provide a measurement system. In an embodiment, the measurement system comprises a measurement instrument described above.

In some embodiments, the measurement system may be configured to perform the signal processing method according to any one of the embodiments described above.

Regarding the further advantages and properties of the measurement system, reference is made to the explanations given above with respect to the signal processing method and the measurement instrument, which also hold for the measurement system and vice versa.

The measurement system may further comprise a device under test, wherein a signal port of the device under test is connected with the signal input.

In some embodiments, the signal port of the device under test may be an output port. Accordingly, the digital signal may be an output signal of the device under test, wherein the digital signal is output via the signal port.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 schematically shows a measurement system according to a first embodiment of the present disclosure;

FIG. 2 schematically shows a measurement system according to a second embodiment of the present disclosure; and

FIG. 3 shows an example of a flow chart of a signal processing method according to an embodiment of the present disclosure.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

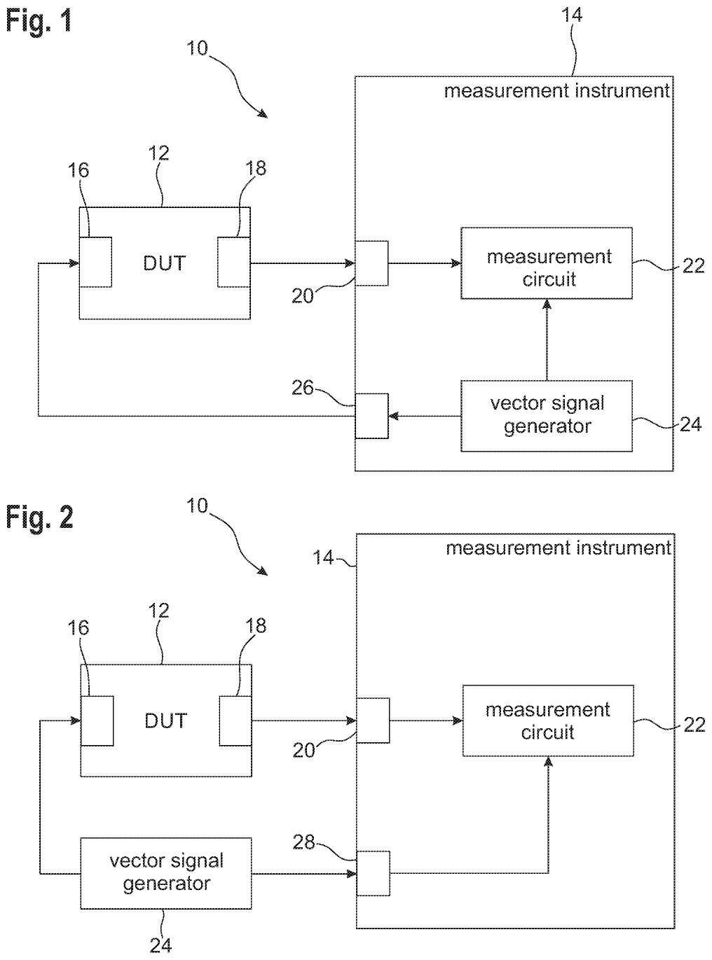

FIG. 1 schematically shows a measurement system 10 formed in accordance with an embodiment of the present disclosure. As shown in FIG. 1, the system 10 comprises a device under test 12 and a measurement instrument 14. The device under test 12 may be established as any electronic device that is configured to generate an electronic signal.

In some embodiments, the device under test 12 may be an electronic component that is used in Wi-Fi applications or in 5G applications. In the particular example shown in FIG. 1, the device under test 12 is established as a two-port device having an input port 16 and an output port 18. For example, the device under test 12 may be established as an amplifier that is configured to amplify an input signal received via the input port 16, and to output a corresponding amplified signal via the output port 18.

As another example, the device under test 12 may be established as a filter that is configured to filter an input signal received via the input port 16 in a predefined manner, and to output a corresponding filtered signal via the output port 18.

However, the device under test 12 may also be established as a one-port device having only a single port, or as a multi-port device having more than two ports, e.g. three, four or more ports.

Without restriction of generality, the device under test 12 is assumed to be a two-port device as illustrated in FIGS. 1 and 2 in the following.

The measurement instrument 14 is established as any type of suitable measurement instrument that is configured to perform the functionalities described below. For example, the measurement instrument 14 may be established as an oscilloscope, for example as a digital oscilloscope, as a signal analyzer, as a vector signal analyzer, as a spectrum analyzer, or as a vector network analyzer.

In the representative embodiment illustrated in FIG. 1, the measurement instrument 14 comprises a signal input 20, a measurement circuit 22, a vector signal generator 24, and a signal output 26. The vector signal generator 24 is configured to generate a test signal that is forwarded to the input port 16 of the device under test 12 via the signal output 26 of the measurement instrument 14.

In general, the test signal is a digital signal having defined arbitrary properties. The exact properties of the test signal depend on the device under test 12 and on the type of measurements that are to be conducted on the device under test 12.

The device under test 12 processes the test signal and generates a digital input signal based on the test signal.

The signal input 20 is connected, for example directly connected with the output port 18 of the device under test 12 in a signal transmitting manner. Therein and in the following, the term “connected in a signal transmitting manner” is understood to denote a cable-based or wireless connection that is configured to transmit signals between the respective devices or components.

The signal input 20 is configured to receive the digital input signal output by the device under test 12. It is noted that further electronic components may be interconnected between the device under test 12 and the signal input 20. However, without restriction of generality it is assumed in the following that the device under test 12 is directly connected with the signal input 20.

The digital input signal received via the signal input 20 of the measurement instrument 14 is forwarded to the measurement circuit 22 for further processing, as will be described in more detail below.

FIG. 2 shows a second embodiment of the measurement system 10, wherein only the differences compared to the first embodiment described above are explained in the following. In contrast to the embodiment described above, the vector signal generator 24 is not integrated into the measurement instrument 14, but is rather established separately from the measurement instrument 14.

The measurement instrument 14 may comprise a further signal input 28 that is connected to the vector signal generator 24 in a signal transmitting manner. The test signal generated by the vector signal generator 24 may be forwarded to the measurement circuit 22 via the further signal input 28. It is noted that a plurality of further measurement setups are possible with the measurement system 10 described above.

While the setups illustrated in FIGS. 1 and 2 are associated with measurements of forward transmission parameters of the device under test 12, the setups can readily be adapted for backward transmission measurements, input reflection measurements and/or output reflection measurements.

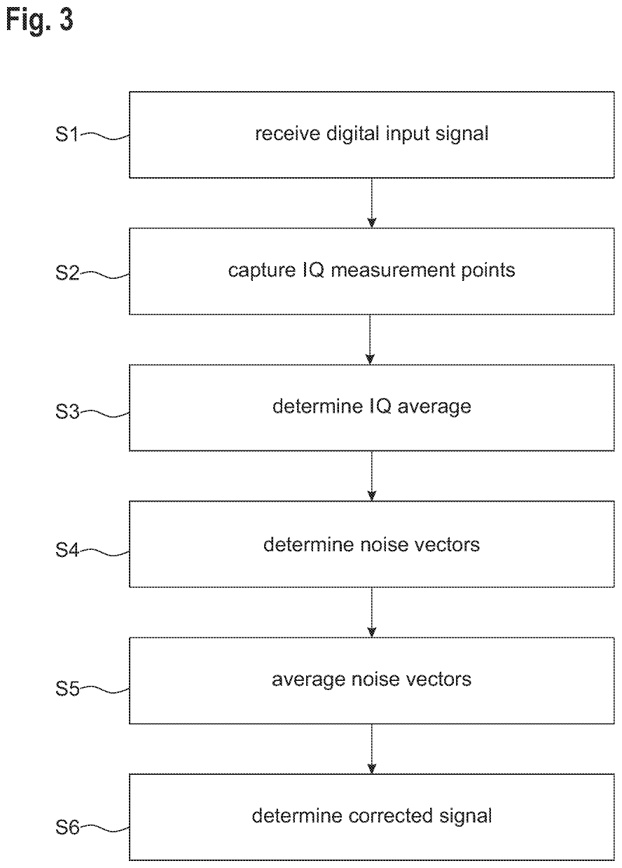

Irrespective of the particular embodiment, the measurement system 10 is configured to perform a signal processing method, an example of which is described below with reference to FIG. 3.

The digital input signal generated by the device under test 12 is received by the signal input 20 and is forwarded to the measurement circuit 22 (step S1).

As already mentioned above, the digital input signal may be received directly from the output port 18 of the device under test 12. Alternatively, the digital input signal may be received from another electronic component in the signal chain that is interconnected between the device under test 12 and the signal input 20.

Without restriction of generality, a particular exemplary case is described in the following, wherein the digital input signal is an IQ signal comprising IQ data. Thus, the digital input signal comprises in-phase data (I data) and quadrature data (Q data), such that the digital input signal comprises amplitude information and phase information.

A first number N₁ of IQ measurement sets associated with the received digital signal are captured by the measurement circuit 22 (step S2).

The captured IQ measurement sets comprise a plurality of IQ measurement points, respectively. In other words, the captured IQ measurement sets comprise a plurality of IQ measurement samples, respectively. Therein, the first number N₁ of IQ measurement sets may correspond to N₁ repetitions of the same measurement.

In general, the IQ measurement sets and the individual IQ measurement points comprise a wanted signal portion (also called useful signal portion) of the digital input signal as well as noise, wherein the noise may originate in the device under test 12, in the measurement instrument 14, for example in the measurement circuit 22 and/or in the vector signal generator 24, and in any electronic components interconnected between the device under test 12 and the measurement instrument 14.

Hereinafter, the noise originating in different sources is assumed to be white Gaussian noise. Further, it is assumed that noise originating in different sources is independent. Thus, complex realizations of the noise can be added as well as the noise powers.

Accordingly, the measured signal (i.e. the IQ measurement sets) are given by the following equation:

$${s}_{meas} = G \cdot {s}_{ref} + {n}_{other} + {n}_{VSA} ( + G \cdot {n}_{VSG} )$$

Therein, sₘₑₐₛ is the measured signal, s_{ref} is an ideal reference signal, i.e. an ideal signal generated by the signal generator 24 that is processed by the device under test 12, n_{VSA} is noise generated by a signal analysis path of the measurement instrument 14 (i.e. by the measurement circuit 22), n_{VSG} is noise generated by a signal generator path of the measurement system 10 (i.e. by the vector signal generator 24), and G is a gain factor.

An IQ average is determined based on the captured IQ measurement sets, thereby obtaining an averaged signal (step S3).

Therein, the determined IQ average corresponds to an IQ average over (N₁−1) of the captured IQ measurement sets.

In some embodiments, for each of the N₁ IQ measurement sets s_{meas,i}, a respective IQ average S_{avg,i} may be determined that corresponds to an average over the other (N₁−1) IQ measurement sets s_{meas,j}, i.e.

$${s}_{a v g , i} = \frac{1}{{N}_{1} - 1} {\sum }_{j = 1 , j \neq i}^{{N}_{1}} {s}_{m e a s , j} .$$

As will be described in more detail below, not all of the IQ averages have to be calculated explicitly. Instead, it is sufficient to determine an IQ average over all N₁ IQ measurement sets, and to multiply the result by a certain factor.

A second number N₂ of noise vectors is determined based on the averaged signal and based on the captured IQ measurement sets (step S4).

In some embodiments, a corresponding noise vector may be determined for each of the IQ measurement sets, i.e. the number N₂ may be equal to the number N₁. Without restriction of generality, N₁=N₂=N is assumed in the following.

The noise vectors correspond to the noise generated by the device under test 12. In other words, the noise vectors comprise only noise generated by the device under test 12 at least up to power-suppressed contributions that are suppressed by 1/a, wherein a=(N−1) is the number of IQ measurement sets that are averaged.

The i-th noise vector n_{corrected,i} is then given by

$${n}_{corrected , i} = {w}_{est , corr} \cdot ( {s}_{meas , i} - {s}_{avg} )$$

Therein, s_{avg} is chosen to be the IQ average over all IQ measurement sets s_{meas,j} except for the IQ measurement point with index “i” in order to ensure that n_{corrected,i} is a valid noise vector.

Further, w_{est,corr} is a weighting factor that will be described in more detail below.

The difference between the i-th IQ measurement set and the average signal s_{avg} can be rewritten as follows:

$${s}_{meas , i} - {s}_{avg , N - 1} = {s}_{meas , i} - \frac{1}{N - 1} {\sum }_{j = 1 , j \neq i}^{N} {s}_{meas , j}$$

$$= {s}_{meas , i} - \frac{1}{N - 1} ( {\sum }_{j = 1}^{N} {s}_{meas , j} - {s}_{meas , i} ) = {s}_{meas , i} + \frac{1}{s - 1} {s}_{meas , i} - \frac{1}{N - 1} {\sum }_{j = 1}^{N} {s}_{meas , j}$$

$$= {s}_{meas , i} ( 1 + \frac{1}{N - 1} ) - \frac{1}{N - 1} {\sum }_{j = 1}^{N} {s}_{meas , j}$$

The average over the other (N−1) IQ measurement sets can be rewritten in terms of the average s_{avg,N} over all IQ measurement sets, thereby obtaining:

$${s}_{meas , i} - {s}_{avg , N - 1} = {s}_{meas , i} ( 1 + \frac{1}{N - 1} ) - \frac{N}{N - 1} \cdot \frac{1}{N} {\sum }_{j = 1}^{N} {s}_{meas , j}$$

$$= {s}_{meas , i} ( 1 + \frac{1}{N - 1} ) - \frac{N}{N - 1} {s}_{avg , N}$$

Thus, the final result for the noise vectors n_{corrected,i} is

$${n}_{corrected , i} = {w}_{est , corr} \cdot \frac{N}{N - 1} \cdot ( {s}_{m e a s , i} - {s}_{avg , N} ) .$$

Accordingly, only a single IQ average s_{avg,N} has to be determined that can be used for determining all noise vectors.

The weighting factor w_{est,corr} is chosen or rather determined such that the differences between the IQ measurement sets and the averaged signal multiplied by the weighting factor correspond to the noise contribution of the device under test.

If power-suppressed noise contributions are neglected, the weighting factor is given by

$${w}_{est , corr} \approx w = \sqrt{\frac{{N}_{total} - {N}_{VSA} - G \cdot {N}_{VSG}}{{N}_{total}}} .$$

Therein, Nₜₒₜₐₗ is a root mean square (RMS) power of the total noise, Nysa is a RMS power of the noise generated by the signal analysis path of the measurement system 10, for example of the measurement instrument 14, and N_{VSG} is a RMS power of the noise generated by the signal generator path of the measurement system 10, for example by the vector signal generator 24.

If power-suppressed contributions are considered for determining the noise vectors, the weighting factor is given by

$${w}_{est , corr} = {w}_{est} ( 1 + \sqrt{\frac{1}{a - 1}} ) - \sqrt{\frac{1}{a - 1}} = \sqrt{\frac{{N}_{total , est} - {N}_{VSA} ( - G \cdot {N}_{VSG} )}{{N}_{total , est}}} ( 1 + \sqrt{\frac{1}{a - 1}} ) - \sqrt{\frac{1}{a - 1}} .$$

Therein, it holds N_{total,est}=a/(a−1)Nₜₒₜₐₗ.

The noise amplitudes nₜₒₜₐₗ corresponding to the RMS noise power can be computed for each IQ measurement set according to nₜₒₜₐₗ=sₘₑₐₛ−s_{avg}. Thus, the RMS power of the total noise can be determined based on the measurements already conducted.

The RMS noise powers N_{VSA} and N_{VSG} can, for example, be measured with an additional measurement, namely by applying a known load to the measurement instrument 14 and/or to the vector signal generator 24.

For example, the known load may be a standard load that can be used for calibrating the measurement instrument 14 and/or the vector signal generator 24.

In some embodiments, the known load may be an external load that is connected to the measurement instrument 14 and/or the vector signal generator 24. Alternatively, the known load may be integrated into the measurement instrument 14 and/or the vector signal generator 24. For example, the measurement instrument 14 and/or the vector signal generator 24 may comprise a switch being configured to selectively connect the known load to the measurement circuit 22 and/or to the vector signal generator 24.

The determined noise vectors are averaged, thereby obtaining an averaged noise vector (step S5).

In some embodiments, amplitudes of the noise vectors n_{corrected,i} may be averaged in order to determine the averaged noise vector n_{avg}. For example, the amplitude of the averaged noise vector n_{avg} may be the RMS amplitude of the noise vectors n_{corrected,i}, i.e.

$$\vert {n}_{a v g} \vert = RMS ( {n}_{corrected , i} ) .$$

The phase of the averaged noise vector may be chosen to be equal to a phase of one of the noise vectors, for example to a phase 41 of a first noise vector n_{corrected,1}.

In this case, the averaged noise vector is given by

$${n}_{a v g} = RMS ( {n}_{corrected , i} ) \cdot exp ( j \cdot {φ}_{1} ) .$$

Alternatively, the phase of the averaged noise vector may be equal to an average of the phases of the noise vectors n_{corrected,i}.

However, it is to be understood that any other suitable averaging technique may be used in order to determine the averaged noise vector, for example any suitable linear averaging technique or any suitable power averaging technique.

A corrected signal is determined based on the averaged signal and based on the averaged noise vector (step S6).

The corrected signal s_{corr} is then given by

$${s}_{c o r r} = {s}_{avg , N} + {n}_{a v g} .$$

Thus, the corrected signal s_{corr} is equal to the sum of the averaged signal s_{avg,N} and the averaged noise vector n_{avg}.

Accordingly, the resulting corrected signal comprises only a useful signal (also called wanted signal) of the device under test 12, namely the averaged signal, and noise contributions of the device under test 12, namely the averaged noise vector.

Based on the corrected signal, a performance of the device under test 12 can be assessed by the measurement circuit 22 with high precision, as noise originating in sources other than the device under test 12 has been removed from the corrected signal.

Moreover, the measurement uncertainty is reduced, as the noise generated by the device under test 12 has been averaged over the IQ measurement sets, which corresponds to an EVM averaging.

Certain embodiments disclosed herein include components that may utilize circuitry (e.g., one or more circuits) in order to implement protocols, methodologies or technologies disclosed herein, operably couple two or more components, generate information, process information, analyze information, generate signals, encode/decode signals, convert signals, transmit and/or receive signals, control other devices, etc. Circuitry of any type can be used. It will be appreciated that the term “information” can be use synonymously with the term “signals” in this paragraph. It will be further appreciated that the terms “circuitry,” “circuit,” “one or more circuits,” etc., can be used synonymously herein.

In an embodiment, circuitry includes, among other things, one or more computing devices such as a processor (e.g., a microprocessor), a central processing unit (CPU), a digital signal processor (DSP), an application-specific integrated circuit (ASIC), a field-programmable gate array (FPGA), a system on a chip (SoC), or the like, or any combinations thereof, and can include discrete digital or analog circuit elements or electronics, or combinations thereof.

In an embodiment, circuitry includes hardware circuit implementations (e.g., implementations in analog circuitry, implementations in digital circuitry, and the like, and combinations thereof). In an embodiment, circuitry includes combinations of circuits and computer program products having software or firmware instructions stored on one or more computer readable memories that work together to cause a device to perform one or more protocols, methodologies or technologies described herein. In an embodiment, circuitry includes circuits, such as, for example, microprocessors or portions of microprocessor, that require software, firmware, and the like for operation. In an embodiment, circuitry includes an implementation comprising one or more processors or portions thereof and accompanying software, firmware, hardware, and the like, thereby forming a special purpose computer or machine that performs one or more protocols, methodologies or technologies described herein.

Various embodiments of the present disclosure or the functionality thereof may be implemented in various ways, including as non-transitory computer program products. A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, program code, computer program instructions, and/or similar terms used herein interchangeably). Such non-transitory computer-readable storage media include all computer-readable media (including volatile and non-volatile media).

Embodiments of the present disclosure may also take the form of an apparatus, system, computing device, computing entity, and/or the like executing instructions stored on computer-readable storage media to perform certain steps or operations. The computer-readable media include cooperating or interconnected computer-readable media, which exist exclusively on a processing or processor system or distributed among multiple interconnected processing or processor systems that may be local to, or remote from, the processing or processor system. However, embodiments of the present disclosure may also take the form of an entirely hardware embodiment performing certain steps or operations.

Various embodiments are described above with reference to block diagrams and/or flowchart illustrations of apparatuses, methods, systems, and/or computer program instructions or program products. It should be understood that each block of any of the block diagrams and/or flowchart illustrations, respectively, or portions thereof, may be implemented in part by computer program instructions, e.g., as logical steps or operations executing on one or more computing devices. These computer program instructions may be loaded onto one or more computer or computing devices, such as special purpose computer(s) or computing device(s) or other programmable data processing apparatus(es) to produce a specifically-configured machine, such that the instructions which execute on one or more computer or computing devices or other programmable data processing apparatus implement the functions specified in the flowchart block or blocks and/or carry out the methods described herein.

These computer program instructions may also be stored in one or more computer-readable memory or portions thereof, such as the computer-readable storage media described above, that can direct one or more computers or computing devices or other programmable data processing apparatus(es) to function in a particular manner, such that the instructions stored in the computer-readable memory produce an article of manufacture including computer-readable instructions for implementing the functionality specified in the flowchart block or blocks.

The computer program instructions may also be loaded onto one or more computers or computing devices or other programmable data processing apparatus(es) to cause a series of operational steps to be performed on the one or more computers or computing devices or other programmable data processing apparatus(es) to produce a computer-implemented process such that the instructions that execute on the one or more computers or computing devices or other programmable data processing apparatus(es) provide operations for implementing the functions specified in the flowchart block or blocks and/or carry out the methods described herein.

It will be appreciated that the term computer or computing device can include, for example, any computing device or processing structure, including but not limited to a processor (e.g., a microprocessor), a central processing unit (CPU), a digital signal processor (DSP), an application-specific integrated circuit (ASIC), a field-programmable gate array (FPGA), a system on a chip (SoC), or the like, or any combinations thereof.

Accordingly, blocks of the block diagrams and/or flowchart illustrations support various combinations for performing the specified functions, combinations of operations for performing the specified functions and program instructions for performing the specified functions. Again, it should also be understood that each block of the block diagrams and flowchart illustrations, and combinations of blocks in the block diagrams and/or flowchart illustrations, or portions thereof, could be implemented by special purpose hardware-based computer systems or circuits, etc., that perform the specified functions or operations, or combinations of special purpose hardware and computer instructions.

In some embodiments, the one or more computer-readable media contains computer readable instructions embodied thereon that, when executed by the one or more computer circuits, sometimes referred to as computing devices, cause the one or more computer circuits to perform one or more steps of any of the methods of claimed subject matter.

In the foregoing description, specific details are set forth to provide a thorough understanding of representative embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure. Further, it will be appreciated that embodiments of the present disclosure may employ any combination of features described herein.

Throughout this specification, terms of art may be used. These terms are to take on their ordinary meaning in the art from which they come, unless specifically defined herein or the context of their use would clearly suggest otherwise.

The present application may reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A and B” is equivalent to “A and/or B” or vice versa, namely “A” alone, “B” alone or “A and B.”. Similarly, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

The embodiments of the invention in which an exclusive property or privilege is claimed are defined as follows:

1. A signal processing method of processing a digital input signal by a measurement instrument, the measurement instrument comprising a signal input, a measurement circuit, and an analysis circuit, the signal processing method comprising the steps of:
receiving, by the signal input, a digital input signal from a device under test;
capturing, by the measurement circuit, a first number N₁ of IQ measurement sets based on the received digital input signal, wherein each IQ measurement set comprises a plurality of IQ measurement points;
determining, by the analysis circuit, an IQ average based on the captured IQ measurement sets, thereby obtaining an averaged signal;
determining, by the analysis circuit, a second number N₂ of noise vectors based on the averaged signal and based on the captured IQ measurement sets; and
averaging, by the analysis circuit, over the determined noise vectors, thereby obtaining an averaged noise vector.

2. The signal processing method of claim 1, wherein the determined IQ average corresponds to an IQ average over (N₁−1) of the captured IQ measurement sets.

3. The signal processing method of claim 1, wherein the first number N₁ is equal to the second number N₂.

4. The signal processing method of claim 1, wherein the noise vectors and/or the averaged noise vector correspond to a noise contribution of the device under test.

5. The signal processing method of claim 1, wherein the noise vectors are free of noise generated by the measurement instrument at least up to a power-suppressed contribution, and/or wherein the averaged noise vector is free of noise generated by the measurement instrument at least up to a power-suppressed contribution.

6. The signal processing method of claim 1, wherein each noise vector determined is associated with one of the captured IQ measurement sets.

7. The signal processing method of claim 6, wherein differences between the IQ measurement sets and the averaged signal are determined in order to determine the noise vectors.

8. The signal processing method of claim 7, wherein the differences between the IQ measurement sets and the averaged signal are multiplied by N₁/(N₁−1) in order to determine the noise vectors.

9. The signal processing method of claim 7, wherein the differences between the IQ measurement sets and the averaged signal are multiplied by a weighting factor in order to determine the noise vectors.

10. The signal processing method of claim 9, wherein the weighting factor depends on at least one of the first number N₁, a root means square (RMS) of a total noise, a RMS noise of an analysis path of the measurement instrument, or a RMS noise of a signal generator path of the measurement instrument.

11. The method of claim 1, wherein amplitudes of the noise vectors are averaged in order to determine the averaged noise vector.

12. The method of claim 1, wherein a corrected signal is determined based on the averaged signal and based on the averaged noise vector, wherein the corrected signal comprises noise generated by the device under test.

13. A measurement instrument, the measurement instrument comprising a signal input, a measurement circuit, and an analysis circuit, the measurement instrument being configured to perform a signal processing method according to claim 1.

14. The measurement instrument of claim 13, wherein the measurement instrument is established as a vector network analyzer, as a signal analyzer, as a spectrum analyzer, or as an oscilloscope.

15. The measurement instrument of claim 13, wherein the measurement instrument is a calibrated measurement instrument, such that a noise contribution of the measurement instrument is known.

16. A measurement system, comprising a measurement instrument according to claim 13.

17. The measurement system of claim 16, further comprising a device under test, wherein a signal port of the device under test is connected with the signal input.
